(19) United States
(12) Patent Application Publication
(10) Pub. No.: US 2026/0068728 A1
(43) Pub. Date: Mar. 5, 2026

(54) FABRICATION PROCESS FOR FORMING A BARRIER LAYER FOR METAL-TOP (METTOP) INTEGRATED CIRCUITS

(71) Applicant: TEXAS INSTRUMENTS INCORPORATED, DALLAS, TX (US)

(72) Inventors: JOSE ARVIN PLOMANTES, DAGUPAN (PH); JEFFREY SOLAS, ILOILO CITY (PH); JOMARI AUSTRIA, MALABON CITY (PH)

(21) Appl. No.: 18/820,978

(22) Filed: Aug. 30, 2024

(51) Int. Cl. H01L 23/00

(52) U.S. Cl. CPC H01L 24/03

(57) ABSTRACT

One example includes a method for fabricating an integrated circuit (IC) device. The method includes fabricating a semiconductor die comprising a metal top (METTOP) structure and forming a barrier layer over the METTOP structure to cover approximately the entirety of the METTOP structure. The method also includes forming a polyimide (PI) layer over the semiconductor die and over a portion of the barrier layer to form a gap that exposes the barrier layer through the PI layer. The method further includes forming a conductive post in the gap over the barrier layer.

### TECHNICAL FIELD

This description relates generally to integrated circuit fabrication systems, and more particularly to a fabrication process for forming a barrier layer for metal-top (METTOP) integrated circuits.

### BACKGROUND

Integrated circuit (IC) packages have long been implemented in computer devices for providing increasingly compact circuits in computer products. Some ICs can be formed as flip-chip devices and/or quad flat no-lead (QFN) packages that may include conductive posts that form electrical contact to associated contact pads on a printed circuit board (PCB). A polyimide (PI) material is often used as part of a fabrication process for IC packages, such as flip-chip or QFN packages. The interaction of the PI material and the metallic layers beneath the PI material can sometimes lead to unintended circuit effects, particularly with respect to the circuit connections to the associated PCB, such as added resistance to the circuit connection.

### SUMMARY

One example includes a method for fabricating an integrated circuit (IC) device. The method includes fabricating a semiconductor die comprising a metal top (METTOP) structure and forming a barrier layer over the METTOP structure to cover approximately the entirety of the METTOP structure. The method also includes forming a polyimide (PI) layer over the semiconductor die and over a portion of the barrier layer to form a gap that exposes the barrier layer through the PI layer. The method further includes forming a conductive post in the gap over the barrier layer.

Another example described herein includes an IC device. The device includes a semiconductor die comprising a METTOP structure and a barrier layer formed over the METTOP structure. The barrier layer can cover approximately the entirety of the METTOP structure. The device also includes a PI layer formed over the semiconductor die and over a portion of the barrier layer to form a gap that exposes the barrier layer through the PI layer. The device further includes a conductive post formed in the gap over the barrier layer.

Another example described herein includes a method for fabricating an integrated circuit (IC) device. The method includes fabricating a semiconductor die comprising a METTOP structure and forming a barrier layer over the METTOP structure. The barrier layer can have an outer periphery that is approximately aligned with an outer periphery of the METTOP structure. The method also includes forming a PI layer over the semiconductor die and over a portion of the barrier layer to form a gap that exposes the barrier layer through the PI layer. The portion of the PI layer can be formed over the semiconductor die abutting the outer periphery of the barrier layer. The method further includes forming a conductive post in the gap over the barrier layer.

Another example described herein includes an IC device. The device includes a semiconductor die comprising a METTOP structure and a barrier layer formed over the METTOP structure. The barrier layer can have an outer periphery that is approximately aligned with an outer periphery of the METTOP structure. The device also includes a PI layer formed over the semiconductor die and over a portion of the barrier layer to form a gap that exposes the barrier layer through the PI layer. The portion of the PI layer can be formed over the semiconductor die abutting the outer periphery of the barrier layer. The device further includes a conductive post formed in the gap over the barrier layer.

### BRIEF DESCRIPTION OF THE DRAWINGS

FIG. 1 is an example block diagram of an integrated circuit (IC) device.

FIG. 2 is an example of an IC device.

FIG. 3 is an example of a first fabrication step of the IC device.

FIG. 4 is an example of a second fabrication step of the IC device.

FIG. 5 is an example of a third fabrication step of the IC device.

FIG. 6 is an example of a fourth fabrication step of the IC device.

FIG. 7 is an example of a fifth fabrication step of the IC device.

FIG. 8 is an example of a sixth fabrication step of the IC device.

FIG. 9 is an example of a seventh fabrication step of the IC device.

FIG. 10 is an example of an eighth fabrication step of the IC device.

FIG. 11 is an example of a ninth fabrication step of the IC device.

FIG. 12 is an example of a fourth fabrication step of the IC device.

FIG. 13 is an example a method for fabricating an IC device.

FIG. 14 is an example a method for fabricating an IC device.

### DETAILED DESCRIPTION

This description relates generally to integrated circuit fabrication systems, and more particularly to a fabrication process for forming a barrier layer for metal-top (METTOP) integrated circuits. In some integrated circuits (ICs), the IC package can be formed as a flip-chip package and/or quad flat no-lead (QFN) package that may include conductive posts that extend from a surface beneath the package to provide electrical contact to associated contact pads on a printed circuit board (PCB). In such packages, a polyimide (PI) material is often used as part of a fabrication process and surrounds the conductive post(s), such as to provide a sturdy dielectric material to protect and shield the device. The interaction of the PI material and the METTOP structure (e.g., aluminum (Al)) that is formed on the device can result in the development of a resistive film between the PI material and the METTOP structure. The resistive film can thus add an unintended resistance to the conductive post, which can provide deleterious effects to the operation of the circuit, particularly in high voltage applications.

To mitigate resistance forming between a METTOP structure and a PI layer, the IC device described herein can be formed such that a barrier layer is formed to completely cover the METTOP structure prior to forming the PI layer. As an example, the barrier layer (e.g., titanium tungsten (TiW)) can have an outer periphery that is approximately aligned with an outer periphery of the METTOP structure. As described herein, the term “approximately aligned” with respect to the peripheries of the barrier layer and the METTOP structure describes that a surface of the barrier layer is in contact with an opposing surface of the METTOP structure in a manner where there is no overlap of one surface with respect to the other, in that no portion of an outer periphery of one surface extends beyond an outer periphery of the other surface. As a result, there is no contact between the METTOP structure and the PI layer, as opposed to conventional circuit devices in which the PI layer is formed before the barrier layer, thus resulting in surface contact between the PI material and the METTOP structure material. Accordingly, the IC device can operate without added undesired resistance at the electrical connection between the conductive post and an associated contact pad that can detrimentally affect operation of the circuit.

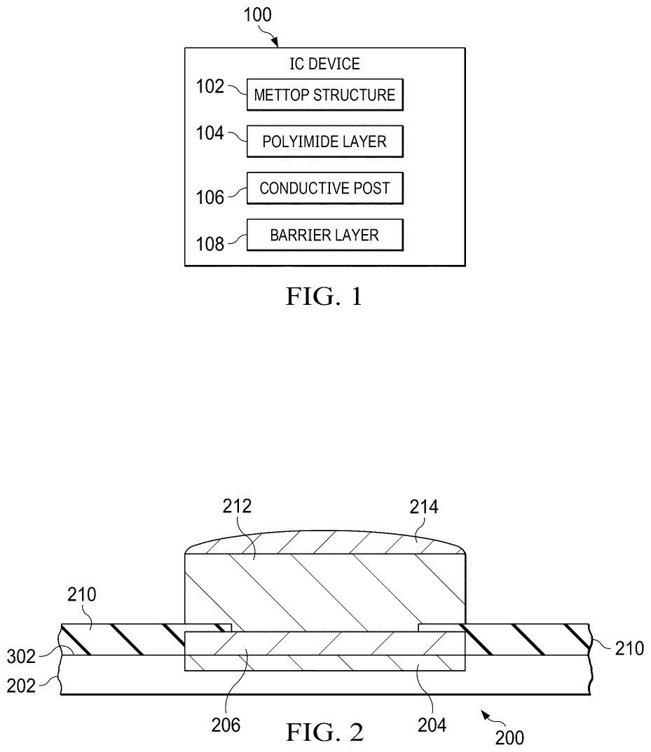

FIG. 1 is an example block diagram of an integrated circuit (IC) device 100. The IC device 100 can be implemented in any of a variety of applications, such as high-voltage circuit applications that are implemented on a flip-chip or quad flat no-lead (QFN) package design. The IC device 100 includes a metal top (METTOP) structure 102 and a polyimide (PI) layer 104. As described herein, the IC device 100 can be fabricated in a manner that mitigates the formation of a resistive film between the METTOP structure 102 and the PI layer 104.

As an example, the METTOP structure 102 can be formed as a conductive metal planar portion that is fabricated in a semiconductor die of the IC device 100. For example, the METTOP structure 102 can be formed from aluminum (Al), and can correspond to a contact interface between the circuitry of the semiconductor die and a conductive post 106 that operates as an input and/or output contact for the IC device 100. As described above, the IC device 100 can be fabricated as a flip-chip device, such that the conductive post 106 and additional layers can be formed up from the METTOP structure 102.

In the example of FIG. 1, the IC device 100 also includes a barrier layer 108. The barrier layer 108 can be formed as a barrier over the METTOP structure 102 to prevent diffusion from the semiconductor die to the conductive post 106. As an example, the barrier layer 108 can be formed from titanium (Ti), titanium tungsten (TiW), or any of a variety of other barrier layer materials. As described herein, the barrier layer 108 can be formed completely over the METTOP structure 102. As an example, the barrier layer 108 can be formed such that an outer periphery of the barrier layer 108 is approximately aligned with the outer periphery of the METTOP structure 102. As a result, there is no contact between the METTOP structure 102 and the PI layer 104. Such an arrangement can be provided by forming the barrier layer 108 prior to the forming the PI layer 104, as described herein. As a result, undesired resistance between the METTOP structure 102 and the PI layer 104 can be mitigated in the IC device 100.

FIG. 2 is an example diagram of an IC device 200. The IC device 200 can be implemented in any of a variety of flip-chip or QFN package applications, such as operating at high voltage amplitudes. The IC device 200 is demonstrated in the example of FIG. 2 in a cross-sectional view to show the relative locations of layers. The IC device 200 is demonstrated by example, and is not intended to be illustrated to scale. The IC device 200 can correspond to the IC device 100 in the example of FIG. 1. Therefore, reference is to be made to the example of FIG. 1 in the following description of FIG. 2.

The IC device 200 includes the semiconductor die 202 that can be fabricated from any of a variety of conventional semiconductor fabrication processes. In the example of FIG. 2, the IC device 200 includes a METTOP structure 204 that is fabricated in the semiconductor die 202, such as within a recess such that surfaces of the METTOP structure 204 and the semiconductor die 202 are flush with respect to each other. The METTOP structure 204 can be fabricated with the semiconductor die 202 to provide an input/output port for the circuitry of the semiconductor die 202. The arrangement of the METTOP structure 204 with respect to the semiconductor die 202 is but one example, and other example arrangements are possible as described herein.

The IC device 200 also includes a barrier layer 206 that is formed over approximately the entirety of the METTOP structure 204. In the example of FIG. 2, the barrier layer 206 has an outer periphery that is approximately aligned with an outer periphery of the METTOP structure 204. The alignment of the outer peripheries of the barrier layer 206 and the METTOP structure 204 is demonstrated in the example of FIG. 2. In addition to the structure demonstrated in the example of FIG. 2, an additional layer of conductive material (e.g., copper (Cu)) can be formed (e.g. sputtered) on the barrier layer 206 on the surface of the barrier layer 206 that is opposite the surface of the barrier layer 206 that is in contact with the METTOP structure 204.

The IC device 200 also includes a PI layer 210 that is formed over the semiconductor die 202 and over a portion of the barrier layer 206, and which thus surrounds a conductive post 212. The conductive post 212 can correspond to an electrical contact structure (e.g., input and/or output) that can provide electrical contact of the semiconductor die 202 with a contact pad of an associated circuit board or other mating device. As an example, the conductive post 212 can be provided via an electroplating process. The conductive post 212 includes a solder top 214 that can provide a low-resistance/impedance coupling to the associated contact pad. As demonstrated in greater detail herein, the PI layer 210 can be formed after formation of the barrier layer 206, thereby ensuring that there is no overlap of the PI layer 210 on the METTOP structure 204 that could result in undesirable resistance for the electric contact between the semiconductor die 202 and the conductive post 212.

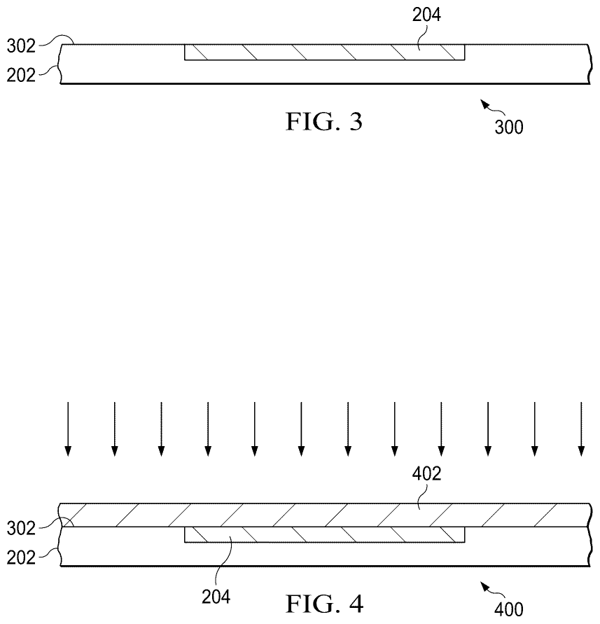

FIGS. 3-12 demonstrate fabrication steps for fabricating the IC device 200 in the example of FIG. 2. Therefore, like reference numbers are used in the examples of FIGS. 3-6 as provided in FIG. 2, and reference to FIG. 2 is to be made in the following examples of FIGS. 3-6.

FIG. 3 is an example of a first fabrication step 300. In the first fabrication step 300, the semiconductor die 202 is fabricated from any of a variety of conventional semiconductor fabrication processes. As described above, the fabrication of the semiconductor die 202 includes fabricating the METTOP structure 204 or flush with a surface 302 of the semiconductor die 202. As described above, the METTOP structure 204 can be formed from aluminum (Al) or any other suitable metal.

FIG. 4 is an example of a second fabrication step 400. In the second fabrication step 400, a barrier material 402 is patterned over the surface 302 of the semiconductor die 202, as well as the METTOP structure 204. In the example of FIG. 4, the barrier material 402 can be titanium tungsten (TiW), and can be formed by sputtering the barrier material 402 as a layer over the semiconductor die 202 and the METTOP structure 204. Therefore, the barrier material 402 overlays the METTOP structure 204.

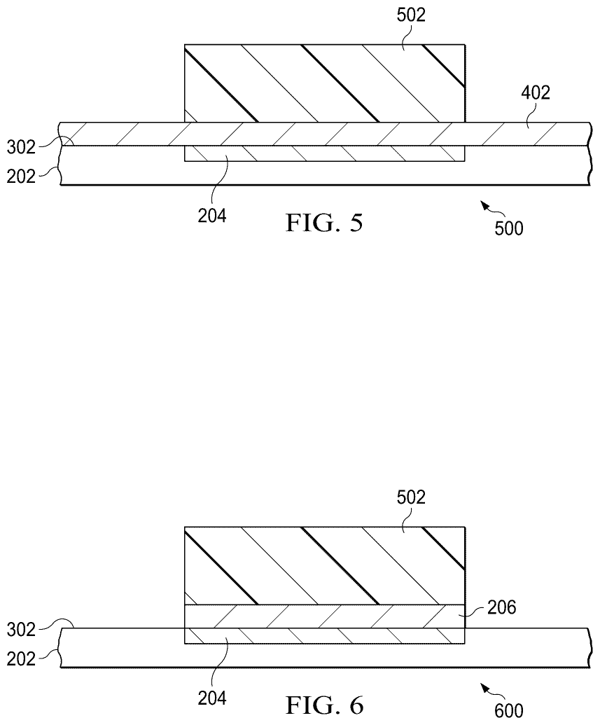

FIG. 5 is an example of a third fabrication step 500. In the third fabrication step 500, a mask (e.g., photomask) 502 is formed over a portion of the barrier material 402. The portion of the barrier material 402 over which the mask 502 can be arranged can be approximately directly over the METTOP structure 204. Therefore, the outer periphery of the mask 502 can be approximately aligned with the outer periphery of the METTOP structure 204.

FIG. 6 is an example of a fourth fabrication step 600. In the fourth fabrication step 600, the portion of the barrier material 402 that is not beneath the mask 502 is removed, thereby revealing the surface 302 of the semiconductor die 202 and forming the barrier layer 206. The removal of the barrier material 402 can be provided in any of a fabrication processes, such as photolithography, etching (e.g., wet or chemical), or mechanical removal (scraping). As demonstrated in the example of FIG. 6, because the outer periphery of the mask 502 is approximately aligned with the outer periphery of the METTOP structure 204, the resultant barrier layer 206 likewise has an outer periphery is approximately aligned with the outer periphery of the METTOP structure 204. As a result, the METTOP structure 204 is substantially completely covered by the barrier layer 206, thereby leaving no portion of the METTOP structure 204 exposed.

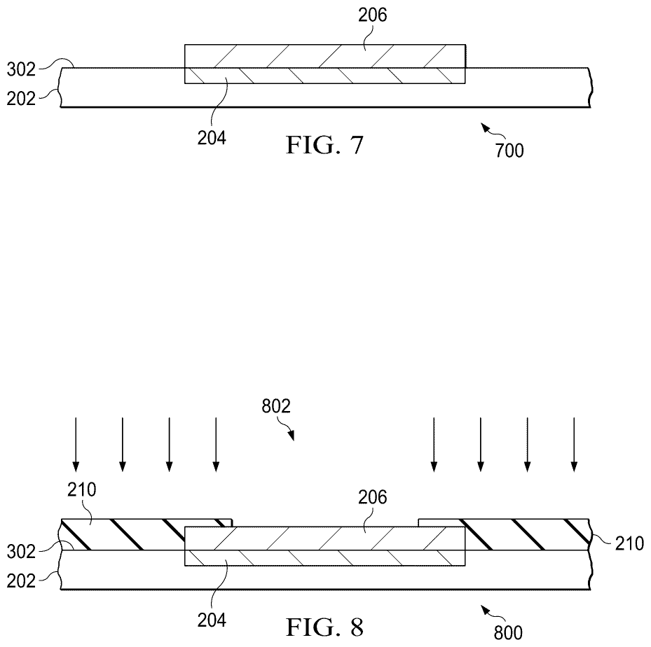

FIG. 7 is an example of a fifth fabrication step 700. In the fifth fabrication step 700, the mask 502 is removed to expose the barrier layer 206. As an example not depicted here, the barrier layer 206 can include a thin layer of conductive material (e.g., copper) that can be provided concurrently with or subsequent to the barrier material 402, such as via a sputtering process.

FIG. 8 is an example of a sixth fabrication step 800. In the sixth fabrication step 800, a PI material is formed over the surface 302 of the semiconductor die 202 and over a portion of the barrier layer 206 to form the PI layer 210. Therefore, the PI layer 210 can completely cover the semiconductor die 202. As an example, the PI material that forms the PI layer 210 can be sputtered on in any of a variety of different ways, and can be any of a variety of polyimides that can provide dielectric characteristics and mechanical sturdiness to the IC device 200. The formation of the PI layer 210 over the portion of the barrier layer 206 can thus form a gap, demonstrated generally at 802, from which the barrier layer 206 is exposed from the PI layer 210. As an example, the gap 802 can be approximately centered on the barrier layer 206 to form a symmetrical opening through the PI layer 210.

As demonstrated in the example of FIG. 8, the PI material that forms the PI layer 210 is provided as abutting the outer periphery of the barrier layer 206, and is therefore not in contact with any portion of the METTOP structure 204. Therefore, the development of a resistive film between the METTOP structure 204 and the PI layer 210 can be mitigated in the fabrication process of the IC device 200.

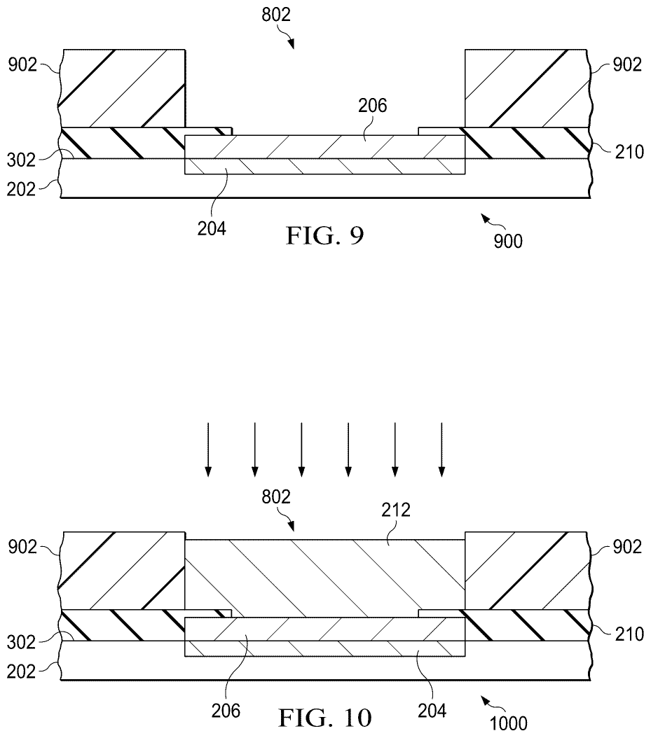

FIG. 9 is an example of a seventh fabrication step 900. In the seventh fabrication step 900, a mask (e.g., photomask) 902 is formed over the PI layer 210. The formation of the mask 902 can be such that the gap 802 and at least a portion of the PI layer 210 is exposed. In the example of FIG. 9, the mask 902 has an inner periphery that is approximately aligned with the outer periphery of the METTOP structure 204 and the barrier layer 206. The alignment of the mask 902 is provided as one example, however. Other alternative examples can be implemented instead, as described herein.

FIG. 10 is an example of an eighth fabrication step 1000. In the eighth fabrication step 1000, a conductive material 1002 is formed in the interior periphery of the mask 902. The conductive material 212 can be any of a variety of electrically conductive materials, such as copper (Cu). As an example, the conductive material 212 can be provided via an electroplating process. The conductive material 212 therefore fills in the gap 802 to form contact with the barrier layer 206 (e.g., or on a thin conductive material on the barrier layer 206).

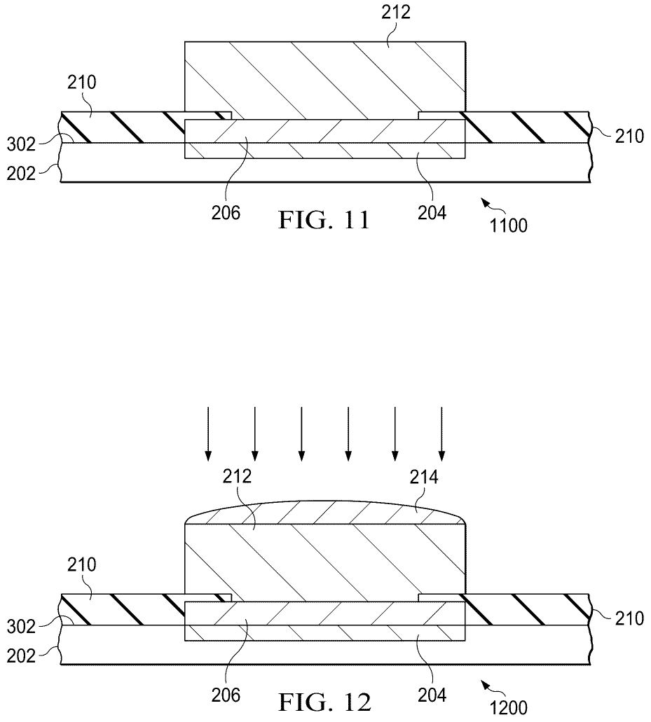

FIG. 11 is an example of a ninth fabrication step 1100. In the ninth fabrication step 1100, the mask 902 is removed. Therefore, the removal of the mask 902 results in exposure of the conductive post 212.

FIG. 12 is an example of a tenth and last fabrication step 1200. In the tenth fabrication step 1200, a solder material is provided on a surface of the conductive post 212 that is opposite the surface of the conductive post 212 that is coupled to the barrier layer 206, and thus forms the solder top 214. The solder material can be any of a variety of standard soldering materials (e.g., tin-silver-copper (SAC)). Accordingly, upon forming the solder top 214 on the conductive post 212, the fabrication of the IC device 200 described herein is complete. The fabrication steps described above in FIGS. 3-12 thus demonstrate a manner for mitigating the formation of a resistive film between the METTOP structure 204 and the PI layer 210 that can result in an undesirable resistance between the conductive post 212 and the semiconductor die 202.

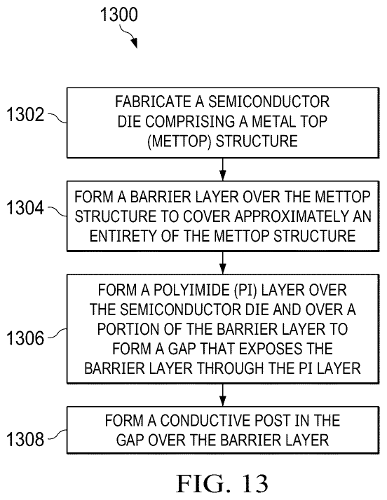

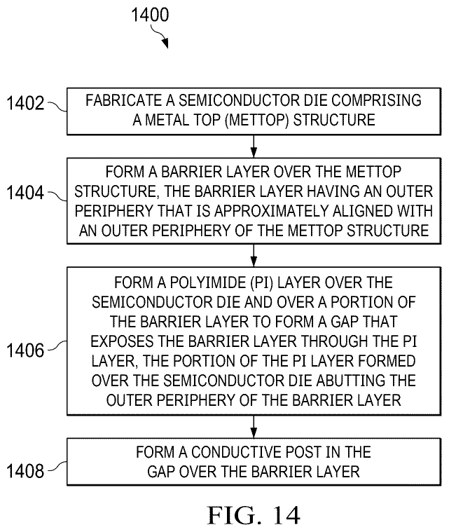

In view of the foregoing structural and functional features described above, a methodology in accordance with various aspects of the present invention will be better appreciated with reference to FIGS. 13 and 14. While, for purposes of simplicity of explanation, the methodology of FIGS. 13 and 14 is shown and described as executing serially, it is to be understood and appreciated that the present invention is not limited by the illustrated order, as some aspects could, in accordance with the present invention, occur in different orders and/or concurrently with other aspects from that shown and described herein. Moreover, not all illustrated features may be required to implement a methodology in accordance with an aspect of the present invention.

FIG. 13 illustrates another example of a method 1300 for fabricating an IC device (e.g., the IC device 100). At 1302, a semiconductor die (e.g., the semiconductor die 202) comprising a METTOP structure (e.g., the METTOP structure 102) is fabricated. At 1304, a barrier layer (e.g., the barrier layer 108) is formed over the METTOP structure to cover approximately the entirety of the METTOP structure. At 1306, a PI layer (e.g., the PI layer 104) is formed over the semiconductor die and over a portion of the barrier layer to form a gap (e.g., the gap 802) that exposes the barrier layer through the PI layer. At 1308, a conductive post (e.g., the conductive post 106) is formed in the gap over the barrier layer portion of the first surface of the semiconductor die.

FIG. 14 illustrates an example of a method 1400 for fabricating an IC device (e.g., the IC device 100). At 1402, a semiconductor die (e.g., the semiconductor die 202) comprising a METTOP structure (e.g., the METTOP structure 102) is fabricated. At 1304, a barrier layer (e.g., the barrier layer 108) is formed over the METTOP structure. The barrier layer can have an outer periphery that is approximately aligned with an outer periphery of the METTOP structure. At 1406, a PI layer (e.g., the PI layer 104) is formed over the semiconductor die and over a portion of the barrier layer to form a gap (e.g., the gap 802) that exposes the barrier layer through the PI layer. The portion of the PI layer formed over the semiconductor die can abut the outer periphery of the barrier layer. At 1408, a conductive post (e.g., the conductive post 106) is formed in the gap over the barrier layer portion of the first surface of the semiconductor die.

In this description, the term “couple” may cover connections, communications, or signal paths that enable a functional relationship consistent with this description. For example, if device A generates a signal to control device B to perform an action, then: (a) in a first example, device A is directly coupled to device B; or (b) in a second example, device A is indirectly coupled to device B through intervening component C if intervening component C does not substantially alter the functional relationship between device A and device B, so device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

Modifications are possible in the described embodiments, and other embodiments are possible, within the scope of the claims.

What is claimed is:

1. A method for fabricating an integrated circuit (IC) device, the method comprising:
fabricating a semiconductor die comprising a metal top (METTOP) structure;
forming a barrier layer over the METTOP structure to cover approximately an entirety of the METTOP structure;
forming a polyimide (PI) layer over the semiconductor die and over a portion of the barrier layer to form a gap that exposes the barrier layer through the PI layer; and
forming a conductive post in the gap over the barrier layer.

2. The method of claim 1, wherein forming the barrier layer comprises:
sputtering a barrier layer material over the semiconductor die and the METTOP structure;
forming a mask over a portion of the barrier layer material, such that the mask has peripheral edges that are approximately aligned with peripheral edges of the METTOP structure;
removing the barrier layer material around the mask; and
removing the mask.

3. The method of claim 1, wherein forming the PI layer comprises forming a polyimide material over the portion of the barrier layer such that no portion of the polyimide material covers any portion of the METTOP structure.

4. The method of claim 1, wherein forming the barrier layer comprises forming the barrier layer to have an outer periphery that is approximately aligned with an outer periphery of the METTOP structure.

5. The method of claim 4, wherein forming the PI layer comprises forming the portion of the PI layer over the semiconductor die abutting the outer periphery of both the barrier layer and the METTOP structure.

6. The method of claim 1, wherein forming the conductive post comprises:
forming a mask over at least a portion of the PI layer, the mask being formed to expose the gap;
filling the gap with a conductive material; and
removing the mask.

7. The method of claim 6, wherein forming the conductive post further comprises providing a solder bump to a first surface of the conductive post opposite a second surface in contact with the barrier layer.

8. An integrated circuit (IC) device comprising:
a semiconductor die comprising a metal top (METTOP) structure;
a barrier layer formed over the METTOP structure, the barrier layer covering approximately an entirety of the METTOP structure;
a polyimide (PI) layer formed over the semiconductor die and over a portion of the barrier layer to form a gap that exposes the barrier layer through the PI layer; and
a conductive post formed in the gap over the barrier layer.

9. The device of claim 8, wherein the conductive post further comprises a solder bump formed on a first surface opposite a second surface in contact with the barrier layer.

10. The device of claim 8, wherein the METTOP structure is formed from aluminum (Al).

11. The device of claim 8, wherein the barrier layer is formed from titanium tungsten (TiW).

12. The device of claim 8, wherein the conductive post is formed from copper (Cu).

13. A method for fabricating an integrated circuit (IC) device, the method comprising:
fabricating a semiconductor die comprising a metal top (METTOP) structure;
forming a barrier layer over the METTOP structure, the barrier layer having an outer periphery that is approximately aligned with an outer periphery of the METTOP structure;
forming a polyimide (PI) layer over the semiconductor die and over a portion of the barrier layer to form a gap that exposes the barrier layer through the PI layer, the portion of the PI layer formed over the semiconductor die abutting the outer periphery of the barrier layer; and
forming a conductive post in the gap over the barrier layer.

14. The method of claim 13, wherein forming the barrier layer comprises:
sputtering a barrier layer material over the semiconductor die and the METTOP structure;
forming a mask over a portion of the barrier layer material, such that the mask has peripheral edges that are approximately aligned with peripheral edges of the METTOP structure;
removing the barrier layer material around the mask; and
removing the mask.

15. The method of claim 13, wherein forming the PI layer comprises forming a polyimide material over the portion of the barrier layer such that no portion of the polyimide material covers any portion of the METTOP structure.

16. The method of claim 13, wherein forming the barrier layer comprises forming the barrier layer to have an outer periphery that is approximately aligned with an outer periphery of the METTOP structure, wherein forming the PI layer comprises forming the portion of the PI layer over the semiconductor die abutting the outer periphery of both the barrier layer and the METTOP structure.

17. The method of claim 13, wherein forming the conductive post comprises:
forming a mask over at least a portion of the PI layer, the mask being formed to expose the gap;
filling the gap with a conductive material; and
removing the mask.

18. An integrated circuit (IC) device comprising:
a semiconductor die comprising a metal top (METTOP) structure;
a barrier layer formed over the METTOP structure, the barrier layer having an outer periphery that is approximately aligned with an outer periphery of the METTOP structure;
a polyimide (PI) layer formed over the semiconductor die and over a portion of the barrier layer to form a gap that exposes the barrier layer through the PI layer, the portion of the PI layer formed over the semiconductor die abutting the outer periphery of the barrier layer; and
a conductive post formed in the gap over the barrier layer.

19. The device of claim 18, wherein the conductive post further comprises a solder bump formed on a first surface opposite a second surface in contact with the barrier layer.

20. The device of claim 18, wherein the METTOP structure is formed from aluminum (Al).

21. The device of claim 18, wherein the barrier layer is formed from titanium tungsten (TiW).

22. The device of claim 18, wherein the conductive post is formed from copper (Cu).
